(19) United States
(12) Patent Application Publication
(10) Pub. No.: US 2013/0082293 A1
(43) Pub. Date: Apr. 4, 2013

(54) LED PACKAGE DEVICE

(71) Applicants: CHIA-CHIANG YANG, Hukou (TW); WEN-LIANG TSENG, Hukou (TW)

(72) Inventors: CHIA-CHIANG YANG, Hukou (TW); WEN-LIANG TSENG, Hukou (TW)

(73) Assignee: ADVANCED OPTOELECTRONIC TECHNOLOGY, INC., Hsinchu Hsien (TW)

(21) Appl. No.: 13/366,376

(22) Filed: Feb. 6, 2012

(30) Foreign Application Priority Data
Sep. 30, 2011 (CN) 201110292749.4

(51) Int. Cl. H01L 33/60

(52) U.S. Cl. 257/98; 257/E33.06

(57) ABSTRACT

An LED package device comprises a substrate, an LED chip, a reflector and a covering layer. The covering layer completely encapsulates the reflector, the LED chip and the substrate to enhance the robustness and unitary integrity of the LED package device; two electrodes comprising two bulges penetrate through the covering layer to reach a base of the LED package device. The LED package device is able to function as a side emitting type of LED package. Front sides of the two bulges are level with a front side of the LED package device and configured for being mounted to a printed circuit board and electrically connecting therewith.

### 1. TECHNICAL FIELD

The disclosure relates generally to a light emitting diode package, and particularly to a side emitting type light emitting diode package device having an enhanced tightness.

### 2. DESCRIPTION OF THE RELATED ART

Light emitting diodes (LEDs) have low power consumption, high efficiency, quick reaction time, long lifetime, and the absence of toxic elements such as mercury during manufacturing. Generally, a reflector is used inside an LED package device to increase the light intensity and render the desired color(s), wherein the reflector may be formed by plastic or polymer such as polyphthalamide (PPA) or other thermoplastic materials. However, a tightness of the combination between the plastic reflector and a metal electrode located on a substrate of the LED package device may reduce a life of the LED package device due to external factors such as moisture or any influence may make the LED disability. To prevent this, a plurality of through holes may be formed in the metal electrode to increase a contact area between the reflector and the substrate. However, forming the through holes in the metal electrodes may result in higher cost and increased time to manufacture the LED package device. Hence, a new design of an LED package device having the potential for an enhanced tightness is required.

### BRIEF DESCRIPTION OF THE DRAWINGS

FIG. 1 is a cross-section of an LED package device of the disclosure.

FIG. 2 is a top view of the LED package device according to FIG. 1.

### DETAILED DESCRIPTION

Exemplary embodiments of the disclosure will be described with reference to the accompanying drawings.

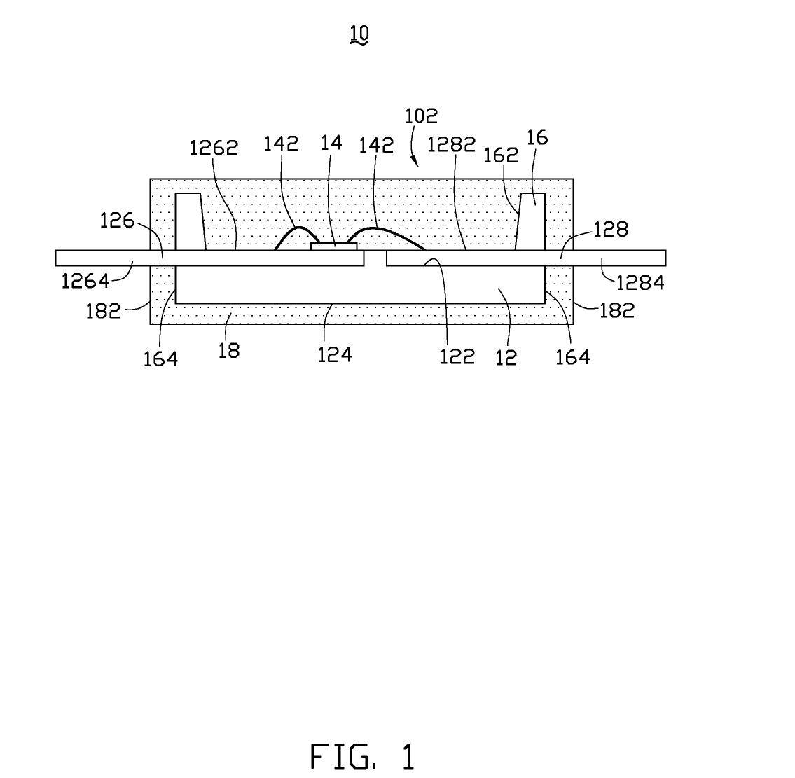

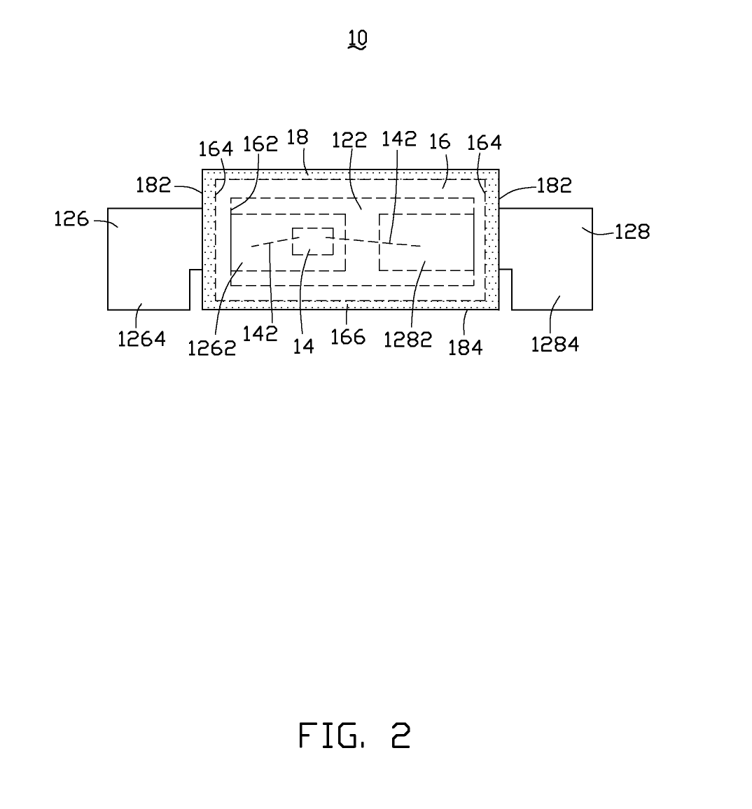

Referring to FIG. 1 and FIG. 2, the disclosure provides an LED package device 10 comprising a substrate 12, an LED chip 14, a reflector 16 and a covering layer 18.

The substrate 12 comprises a top surface 122, lateral sides 164 extending downwardly from the top surface 122 and a bottom surface 124 connected to bottom ends of the lateral sides 164 and opposite to the top surface 122. The substrate 12 can be made of ceramic, silicon or plastic. In the embodiment, two electrodes 126, 128 are separately located on the top surface 122 of the substrate 12, wherein one of the electrodes 126, 128 is a cathode and the other is an anode. The two electrodes 126, 128 comprise a first and second bonding portion, 1262 and 1282, located on the top surface 122 of the substrate 12, and two bulges 1264 and 1284 respectively extending from two opposite ones of the lateral sides 164 of the substrate 12.

The LED chip 14 is disposed on one of the two electrodes 126, 128 and electrically connected to the two electrodes 126, 128. The LED chip 14 has a top face (not labeled) through which light generated by the LED chip 14 emits. In the embodiment, the LED chip 14 is disposed on the first bonding portion 1262 and electrically connected to the first and second bonding portions 1262, 1282 via two conductive wires 142. Alternatively, the LED chip 14 can be disposed on the two electrodes 126, 128 and electrically connected thereto by flip chip bonding or eutectic bonding (not shown).

The reflector 16 is located on the top surface 122 of the substrate 12 and surrounds the LED chip 14. The reflector 16 can be polyphthalamide (PPA), plastic, epoxy or any polymer and can be formed by an insert molding process. In the embodiment, the reflector 16 comprises a depression 162 on the top surface 122 of the substrate 12, wherein the first and second bonding portions 1262, 1282 are located on a bottom of the depression 162. The LED chip 14 is disposed inside the depression 162 so that light emitted from the LED chip 14 can be directed to an opening 102 of the depression 162, which is the light emitting face of the LED package device 10.

The covering layer 18 completely encapsulates the LED chip 14, the reflector 16 and the substrate 12, whereby tightness of the LED package device 10 is enhanced. In the embodiment, the two bulges 1264, 1284 respectively penetrate though two lateral ends 182 of the covering layer 18 from two lateral sides 164 of the substrate 12, and then expand forwardly to reach to a front side 184 of the LED package device 10. Front sides of the two bulges 1264, 1284 are level with each other and the front side 184 of the LED package device 10. When mounted to a printed circuit board (not shown), the front sides of the bulges 1264, 1284 together with the front side 184 of the LED package device 10 are mounted on the printed circuit board. The front sides of the bulges 1264, 1284 are electrically connected to a circuit on the printed circuit board. Moreover, the light emitting face of the LED package device 10 is perpendicular to the front side 184 of the LED package device 10. Thus, the LED package device 10 can function as a side emitting type LED package device on the printed circuit board. The covering layer 18 is transparent and can comprise a luminescent conversion element (not labeled) for producing light with multiple wavelengths. The covering layer 18 can be of thermoplastic or thermosetting materials and be formed by an insert molding process.

Accordingly, the covering layer 18 completely encapsulates the reflector 16, the LED chip 14 and the substrate 12 to enhance the tightness of the LED package device 10; only the two electrodes 126, 128 comprising the two bulges 1264, 1284 penetrate through the covering layer 18 to reach the front side 184 of the LED package device 10. Therefore, the LED package device 10 is easy to manufacture so as to be an LED package device emitting light from the side, and having an enhanced tightness.

It is to be understood, however, that even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An LED package device, comprising:
a substrate, having a top surface, lateral sides adjacent to the top surface and a bottom surface opposite to the top surface, two electrodes located on the top surface of the substrate;
an LED chip, disposing on the substrate and electrically connecting to the two electrodes;
a reflector, located on the top surface of the substrate and surrounding the LED chip; and
a covering layer, encapsulating the LED chip, the reflector and the substrate, wherein the two electrodes comprises two bulges respectively penetrating though two lateral ends of the covering layer from two lateral sides of the substrate.

2. The LED package device as claimed in claim 1, wherein the substrate is made by ceramic, silicon or plastic material.

3. The LED package device as claimed in claim 1, wherein the two electrodes comprise an anode and a cathode.

4. The LED package device as claimed in claim 3, wherein the two electrodes comprises a first bonding portion and a second bonding portion.

5. The LED package device as claimed in claim 4, wherein the LED chip is disposed on the first bonding portion and electrically connects to the first and second bonding portions by two conductive wires.

6. The LED package device as claimed in claim 4, wherein the reflector comprises a depression on the top surface of the substrate, the first and second bonding portions are located on a bottom of the depression.

7. The LED package device as claimed in claim 6, wherein an opening of the depression is a light emitting face of the LED package device.

8. The LED package device as claimed in claim 1, wherein the reflector is made by polyphthalamide (PPA), plastic, epoxy or any polymer.

9. The LED package device as claimed in claim 1, wherein the covering layer is transparent and made by thermosetting or thermoplastic material.

10. The LED package device as claimed in claim 1, wherein the reflector and the covering layer are formed by an insert molding process.

11. The LED package device as claimed in claim 1, wherein the two bulges respectively extend from the two lateral ends of the covering layer to reach a front side of the LED package device.

12. The LED package device as claimed in claim 11, wherein front sides of the two extending bulges are level with the front side of the LED package device, the front sides of the two extending bulges being configured for being mounted to a printed circuit board and electrically connecting therewith.

13. The LED package device as claimed in claim 1, wherein the covering layer comprises a luminescent conversion element.

14. A side emitting type LED package device, comprising:
a substrate, having a top surface, two lateral sides adjacent to the top surface and a bottom surface opposite to the top surface;
two electrodes, located on the top surface of the substrate, comprising two bulges respectively extend from the two lateral sides of the substrate to reach a front side of the side emitting type LED package device;
an LED chip electrically connecting to the two electrodes, the LED chip having a top face for emitting light, the top face being perpendicular to the front side;
a reflector, located on the top surface of the substrate and surrounding the LED chip; and
a covering layer, encapsulating the LED chip, the reflector and the substrate, wherein front sides of the two bulges are level with the front side of the side emitting type LED package device.

15. The side emitting type LED package device as claimed in claim 14, wherein the two electrodes comprise an anode and a cathode.

16. The side emitting type LED package device as claimed in claim 15, wherein the two electrodes comprises a first bonding portion and a second bonding portion.

17. The side emitting type LED package device as claimed in claim 16, wherein the LED chip is disposed on the first bonding portion and electrically connects to the first and second bonding portions by two conductive wires.

18. The side emitting type LED package device as claimed in claim 16, wherein the reflector comprises a depression on the top surface of the substrate, and the first and second bonding portions are located on a bottom of the depression.

19. The side emitting type LED package device as claimed in claim 18, wherein an opening of the depression is a light emitting face of the side emitting type LED package device.

20. The side emitting type LED package device as claimed in claim 14, wherein the two bulges respectively penetrate out of two lateral ends of the covering layer and extend to the front side of the side emitting type LED package device.
